(19) United States
(12) Patent Application Publication
(10) Pub. No.: US 2008/0017985 A1
(43) Pub. Date: Jan. 24, 2008

(54) ELECTRONIC DEVICE WITH A PLURALITY OF SUBSTRATES AND METHOD FOR MANUFACTURING SAME

(75) Inventor: Thomas Kilger, Regenstauf (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Muenchen (DE)

(21) Appl. No.: 11/780,808

(22) Filed: Jul. 20, 2007

(30) Foreign Application Priority Data
Jul. 21, 2006 (DE) 10 2006 033 870.7

(51) Int. Cl. H01L 23/48; H01L 21/00

(52) U.S. Cl. 257/738; 438/106; 257/E23.01; 257/E21.002

(57) ABSTRACT

An electronic device with a plurality of substrates and method for manufacturing same is disclosed. One embodiment provides three-dimensional wiring structure including a basis substrate that includes recesses in the edge region of which electroconductive elements are arranged which cooperate with the electric contact points of substrates that are arranged on the basis substrate in that projections of the substrates are plugged into the recesses. The substrates, in the mounted state, are each mechanically coupled via the projections, and the integrated circuits and/or the electronic devices of the substrates are electrically connected with the conductive elements of the basis substrate.

### CROSS-REFERENCE TO RELATED APPLICATIONS

This Utility Patent Application claims priority to German Patent Application No. DE 10 2006 033 870.7 filed on Jul. 21, 2007, which is incorporated herein by reference.

### BACKGROUND

The present invention relates in general to an electronic device with a number of substrates that are coupled with each other via a three-dimensional wiring structure.

The invention relates further to a method for manufacturing an electronic device with a number of substrates or chips with integrated circuits on a basis substrate, wherein the electric contacts of the integrated circuits on the substrates are contacted with conductive elements on the basis substrate via a three-dimensional wiring structure.

In particular electronic semiconductor devices based on a lead frame technology offer, like the leadless packages, no or only very restricted possibilities for wiring, disentanglement, and/or through-contacting. Multilayer systems are, for instance, known, in which a plurality of substrates are stacked in parallel arrangement and metal intermediate layers of a plastic material or of ceramics are used. These are multilayer substrates in which the arrangement of a plurality of substrates in an electronic device is performed by stacking the substrates to form a stack. These known multilayer substrates have the disadvantage that they have a relatively large space requirement.

To electrically couple the integrated circuits on the different substrates of an electronic device, their contact points are bonded to each other via wirings. One of the most common bonding methods is wire bonding, wherein wire bonds are formed between electric contact points of the integrated circuit and fingers of a lead frame. Many variations of this method are known in which, for instance, the integrated circuit is directly mounted on the circuit board and the wire bonds are formed directly between the circuit board and the integrated circuit. In other variations, a plurality of stacked integrated circuit are connected to each other with wire bonds. In other variations, integrated circuits are arranged on opposite surfaces of the circuit board. These wire bonds have the disadvantage that they are complex to manufacture and have a high space requirement.

In a further common packing method, “flip chips” are used. Flip chips are integrated circuits that comprise electric contacts on one of their main faces and are adapted to be placed on the surface of a substrate with this main face downward, wherein the electric contacts of the flip chips are congruent with the corresponding electric contacts of the substrate. Special measures have to be taken to ensure that all the respective contact pairs will meet, despite any irregularity that might exist on the surface of the integrated circuit or of the substrate. The space between the flip chip and the substrate may subsequently be filled with an “underfilling” layer. The known use of flip chips has also a high space requirement on the substrate and is complex due to the special measures for ensuring the electric contacting of the flip chips, and thus cost-intensive. Another disadvantage consists in that the dimension of the devices has to increase with an increasing number of chips from the bottom to the top.

There are also known substrates that are at least partially manufactured of a flexible material (flex substrates or rigid-flex-rigid substrates) and which can be deformed or bent. Bent substrates are usually manufactured to MID devices (molded interconnect device). Furthermore, flex substrates or rigid-flex-rigid substrates may be molded or packed, respectively prior to the applying of chips in a bent form already (“premold package”). Substrates that are angled and molded after the applying of the chips are also flex substrates or rigid-flex-rigid substrates. A disadvantage of these flex substrates or rigid-flex-rigid substrates is the complicated and thus costly way of manufacturing. Furthermore, a vertical line-up of the chips can be realized with complicated flex substrates or rigid-flex-rigid substrates only. A vertical arrangement of a plurality of substrates or chips in a device has so far only been possible with cost-intensive special processes such as complicated wire bonding, soldering, and gluing processes.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1A illustrates a schematic representation of a front view on a substrate for an electronic device in accordance with a first embodiment.

FIG. 1B illustrates a schematic representation of a cross-section through the substrate for an electronic device illustrated in FIG. 1A in accordance with a first embodiment.

FIG. 2A illustrates a schematic representation of a front view on a basis substrate for an electronic device in accordance with one embodiment.

FIG. 2B illustrates a schematic representation of a cross-section through a part of the basis substrate for an electronic device illustrated in FIG. 2A in accordance with another embodiment.

FIG. 3A illustrates a schematic representation of the situation prior to the bonding of the substrate illustrated in FIGS. 1A and 1B and of the basis substrate illustrated in FIG. 2A in accordance with one embodiment of the method.

FIG. 3B illustrates a schematic representation of the situation after the bonding of the substrate illustrated in FIGS. 1A and 1B and of the basis substrate illustrated in FIG. 2A in accordance with one embodiment of the method.

FIG. 4A illustrates a schematic representation of the situation prior to the bonding of a substrate with a basis substrate in accordance with a second embodiment.

FIG. 4B illustrates a schematic representation of the situation after the bonding of a substrate with a basis substrate in accordance with a second embodiment.

FIG. 5 illustrates a schematic representation of an electronic device in accordance with a third embodiment.

FIG. 6 illustrates a schematic representation of an electronic device in accordance with a fourth embodiment.

FIG. 7 illustrates a schematic representation of a cross-section through an electronic device in accordance with a fifth embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One or more embodiments provide an electronic device that stands out by a small device volume and by a simple construction. One or more embodiments provide a method for manufacturing electronic devices by which highly integrated devices with a three-dimensional wiring structure are easy to manufacture.

One or more embodiment an electronic device with a basis substrate and a number of further substrates that are connected with the basis substrate via a three-dimensional wiring structure, wherein the number of substrates each comprise one or a plurality of integrated circuits and/or electronic devices as well as electric contact points for electrically contacting the integrated circuits and/or electronic devices, and wherein the number of substrates are each provided with at least one projection that extends from the substrate, while the basis substrate comprises a number of recesses that are formed such that they are adapted to incorporate the respective projection of the substrate, characterized in that the basis substrate comprises electroconductive elements that are arranged in the edge region of a recess so as to cooperate with the electric contact points of the substrates, so that the substrates are, in the mounted state, each mechanically coupled via the projection accommodated in the recesses, and the integrated circuits and/or the electronic devices of the substrates are electrically connected with the electroconductive elements of the basis substrate.

Embodiments of the invention render it possible to arrange and pack substrates with integrated circuits on a basis substrate, wherein the substrates only require a small portion of the surface of the basis substrate. Accordingly, the embodiments of the invention enable the bonding of an increased number of integrated circuits or other electronic devices to a substrate without increasing the surface of the substrate.

Substrates or chips can be arranged on a common basis substrate on a small face, in particular be lined up vertically side by side and be connected electrically with each other via a simple vertical wiring structure. Later, the basis substrate may serve as a basic substrate for the connection to the circuit board of the user.

With the present invention, the number of integrated circuits that can be provided for a given substrate surface is increased. The total thickness of the combination of the substrate and the integrated circuit is reduced vis-à-vis arrangements in which the integrated circuit rests on an outer face of the substrate.

Since no wire bonds are required, it is possible to connect the contact points of the integrated circuits with other devices by shorter electric connection paths vis-à-vis the method of wire bond packing. This results in more robust signals with less signal distortion at very high operating frequencies.

The substrate offers an effective protection of the integrated circuits within the electronic device.

In some sensors or optoelectronic components it is necessary to perform the binding to the basis substrate in parallel to the basis substrate or to the circuit board, respectively. This means that e.g., the pressure tube, the magnetic field, or the optical fiber have to enter the package in parallel to the basis substrate. An optimal binding is ensured if the pressure sensor chip, the Hall sensor, or the light sensor/sender chip are oriented vertically to the plane of the basis substrate. The common bonding techniques are, however, conceived such that the chip is first of all applied in parallel to a substrate. Thus, the problem has been shifted to bending the substrate after the mounting of the chips by using flex substrates or rigid-flex-rigid substrates and to processing it in the bent state.

With the present present invention, substrates can be arranged, after their preprocessing, to stand upright on the basis substrate, so that the substrates, in the mounted state, are each oriented substantially vertically with respect to the basis substrate. Instead of substrates with integrated circuits, chips or SMDs (“surface mount device”) with any kind of electronic devices may also be “plugged” on the basis substrate, wherein a vertical orientation with respect to the basis substrate can also be achieved for the chips or the SMDs (“surface mount device”).

In accordance with one or more embodiments, the bonding of the substrates may be performed after SMDs (“surface mount device”), chips, or other electronic devices have been applied on the substrates by using standard semiconductor or SMD mounting processes. The substrates may also be the chips themselves, suitable circuit board materials such as FR4, ceramics, or suitable lead frames. The bonding of the substrates may be performed during the manufacturing of the package or during SMD mounting of the user.

In one embodiment, at least one conductive element on the basis substrate is formed as a solder ball. In one embodiment, the solder balls on the basis substrate are directly adjacent to the edge of the recess or milling, respectively.

This way, the solder balls may be used as three-dimensional bonding pieces between two vertically arranged two-dimensional substrates for electrical contacting. The solder balls on the basis substrate may further have a cutting area that is particularly well suited for contacting a contact face. To this end, the cutting area of the solder balls extends on the basis substrate preferably in the region of the maximum diameter of the solder ball.

These cutting areas of the solder balls on the basis substrate are contacted by the corresponding contact points of the substrate during the insertion of the projection of the substrate in the recess in the basis substrate, and thus an electric connection between the substrate and the basis substrate is established. In order to support this automatic electric contacting during the plugging of the substrate in the basis substrate, the cutting areas of the cut solder balls on the basis substrate are directly adjacent to the edge of the recess, so that the cutting areas of the cut solder balls on the basis substrate are each aligned with the edge of the recess.

In another embodiment, the cutting area of the cut solder balls on the basis substrate may at least partially have an inclined orientation deviating from the alignment of the recess so as to support the electric contacting during the plugging of the projection from the substrate in the recess in the basis substrate by using conically extending cutting areas of the solder balls.

Likewise, the contact points for the electric contacting of the integrated circuits and/or electronic devices on the substrate may be formed as solder balls. The contact points formed as solder balls on the substrate are preferably directly adjacent to the projection of the substrate, so that they automatically contact the conductive elements of the basis substrate in the edge region of the recess during the plugging of the projection from the substrate in the recess in the basis substrate.

The solder balls of the contact points on the substrate may also have a cutting area that extends preferably in the region of the maximum diameter of the solder ball. The cutting area of the cut solder balls on the substrate is oriented substantially vertically to the orientation of the projection of the substrate in order that the cutting area of the solder balls may get into contact in parallel with the contact face of the conductive elements on the basis substrate.

The conductive elements on the basis substrate are arranged such that they correspond with the electric contact points on the substrates in the mounted state so as to establish an electric contact. Additionally, the conductive elements on the basis substrate and the corresponding electric contact points on the substrates may be arranged such that, in the mounted state, a clamping effect results therebetween, which supports the electric contact. As basis substrate, a TSLP lead frame (“thin small leadless package”) may be used, which does not comprise any contact legs at its sides, but merely contact faces on its front or rear sides.

Consequently, either the contact points on the substrate for the electric contacting of the integrated circuits and/or the electronic devices on the substrate may be formed as solder balls, then the corresponding conductive elements on the basis substrate are formed as contact face. The conductive elements on the basis substrate may be formed as solder balls, then the corresponding contact points on the substrate for the electric contacting of the integrated circuits and/or electronic devices on the substrate should be formed as contact face. This way, a solder ball or the cutting area of a solder ball, respectively, will always meet a contact face and an optimum electric contact will be guaranteed.

The dimensions of the recess in the basis substrate correspond substantially to the dimensions of the projection of a substrate, so that a plug connection according to the principle of a pivot/groove connection results between the recess in the basis substrate and the projection of the substrate in the mounted state. The length by which the projection extends from the substrate corresponds preferably to the thickness of the basis substrate, so that the projection plugged into the recess of the basis substrate does not project over the other side of the basis substrate.

In accordance with a further embodiment, the recess in the basis substrate and the projection of a substrate are each formed such that a clamping effect results between the recess in the basis substrate and the projection of the substrate in the mounted state. Thus, the mechanical coupling of the substrate to the basis substrate may be ensured.

The projection of the substrate may be provided at the edge of only one side of the substrate, wherein the projection is preferably formed such that it extends over a majority of the corresponding side of the substrate. A plurality of projections may also be provided at one side of the substrate which are each adapted to be introduced into correspondingly shaped recesses in the basis substrate during the arrangement of the substrate on the basis substrate. Moreover, at least one projection each may be provided at several sides of the substrate, so that a substrate can mechanically be coupled in the above-mentioned manner via several sides with other substrates.

The principle of the mechanical coupling of the substrates consists in that a substrate includes a projection on one side which is formed such that it enables an anchoring in another substrate or the basis substrate, respectively, which includes, for this purpose, a corresponding recess or milling, respectively, or a corresponding long hole. The projection of the first substrate may engage in this recess or milling, respectively, and establish a mechanical fixing. By a suitable choice of the breadth of the recess and the breadth of the projection, other angles than 90° may also be achieved between the substrates. To this end, the distances of the conductive elements of the basis substrate formed as solder balls or the distances of the contact points of the substrates formed as solder balls have to be adapted appropriately.

In accordance with a further embodiment of the electronic device, the number of substrates include at least one chip with one or a plurality of integrated circuits and/or electronic devices. This means that, instead of substrates with integrated circuits, chips or SMDs (“surface mount device”) with any kind of electronic devices may also be arranged on the basis substrate, wherein also the chips or SMDs can be arranged with a vertical orientation with respect to the plane of the basis substrate. Simultaneously with the mechanical coupling, the integrated circuits and/or electronic devices on the substrate, chips, or SMDs are electrically contacted via the electric contacts and the conductive elements on the basis substrate.

To finish the manufacturing of an electronic device, it is, as a rule, provided with a “package” or a housing, respectively, in that it is, for instance, molded or cast with a cast resin. The package initially comprises a plurality of devices in the form of a “substrate bar”. Subsequently, the devices of the substrate bar are individualized by sawing.

In accordance with a further embodiment, the electronic device comprising the basis substrate and the substrates arranged thereon is at least partially surrounded by a package, wherein at least some of the conductive elements of the basis substrate and/or the contact points of the substrates remain contactable from outside the package. In one embodiment, at least some of the conductive elements of the basis substrate and/or of the contact points of the substrates constitute a part of the outer face of the package.

Such contact points that constitute a part of the outer face of the package may be generated in that the sawing apart of the substrate bar to the individual device packages is performed such that the solder balls of the contact points are also cut along therewith. Thus, a respective part of the contact points formed as solder balls remains in the package, while the cutting area of the solder balls generated by the sawing forms a part of the outer face of the package and may serve as an electric connection. If a plurality of substrates provided with chips are held side by side during molding, a horizontal SiP (“System in Package”) may also be generated.

In accordance with yet another embodiment of the electronic device, at least the two outer substrates and/or the basis substrate comprise shield layers. To this end, the outer faces or the outer substrates of the electronic device, i.e. the first and the last substrate of the vertical substrates, the basis substrate at the bottom, the cover, the two long sides, and the two front sides, are preferably designed such that they each comprise large shield faces on their outer layer. Thus, it may be achieved that the interior of the electronic device formed this way is shielded from external electromagnetic scattered radiation and the inherent radiation is reduced.

Another embodiment provides a method for manufacturing an electronic semiconductor device with a basis substrate and a number of further substrates that are connected with the basis substrate via a three-dimensional wiring structure, the method includes:

providing at least one substrate with electric contact points and at least one projection that extends from the substrate;

providing a basis substrate with at least one recess that is formed such that it is configured to accommodate the projection of a substrate, and with conductive elements that are arranged in the edge region of the recess;

mounting the substrate on the basis substrate by introducing the at least one projection of the substrate into a recess in the basis substrate;

contacting the contact points on the substrate via the conductive elements on the basis substrate.

In accordance with one embodiment of the method according to the invention, the integrated circuits and/or electronic devices on the substrate are electrically contacted via the electric contacts of the substrate and the conductive elements on the basis substrate. Thus, the substrates in the mounted state are each mechanically coupled via the projections accommodated in the recesses, and simultaneously the integrated circuits and/or the electronic devices of the substrates are electrically connected with the conductive elements of the basis substrate.

Another embodiment of the method includes the process of fusing the contact points of the substrates with the corresponding contact faces on the basis substrate by heating. As soon as the substrates have been arranged on the basis substrate in the desired manner and have been introduced into the recesses in the basis substrate via their projections, the contact points of the substrates may be soldered with the corresponding contact faces on the basis substrate. This is performed in that the contact points of the substrates formed as solder balls are fused by heating and are thus bonded to the corresponding contact faces on the basis substrate. Accordingly, the conductive elements on the basis substrate formed as solder balls may also be fused by heating and thus be bonded to the corresponding contact faces of the substrates.

Following the contacting, the electronic device with the basis substrate and the substrates arranged thereon may at least partially be surrounded by a package. This is, for instance, performed by coating the electronic device with a packing material such as a cast resin. To facilitate the electric contacting of the electronic device even after the packing, the conductive elements of the basis substrate and/or the contact points of the substrates remain, at least partially contactable from outside the package.

One advantage of the proceeding according to the invention consists in that two-dimensional substrates can first of all be provided with solder balls, chips, electronic devices, or wires by standard processes, and subsequently be nested and be further processed to form an electronic device.

In one embodiment of the method, the package of the electronic device is subsequently cut such that a respective part of the conductive elements of the basis substrate formed as solder balls and/or of the contact points of the substrates formed as solder balls remains in the package, and that the cutting area of the solder balls forms a part of the outer face of the package and can be used as exposed, solderable connection.

This cutting is performed preferably during the individualization of the ready-processed electronic devices where the devices are separated by sawing, so that the solder balls of the contact points are also cut along therewith. Thus, a respective part of the contact points formed as solder balls remains in the package, while the cutting area of the solder balls generated by the sawing forms a part of the outer face of the package and may serve as an electric connection.

On principle, the present invention suggests to mechanically couple two substrates with integrated circuits with one another and, in so doing, electrically connect them via a three-dimensional wiring structure. The electric connections are established between contact points of the integrated circuits on the substrates which are preferably formed as solder balls. In accordance with one embodiment, these solder balls are arranged in the edge region of the substrate and are preferably flush with the edge of the substrate. It is particularly advantageous if these solder balls are cut approximately in two halves, so that the cutting area is flush with the edge of the substrate. The contact points of the substrate are electrically connected by wiring, e.g., for bonding the integrated circuit to other devices mounted on the substrate.

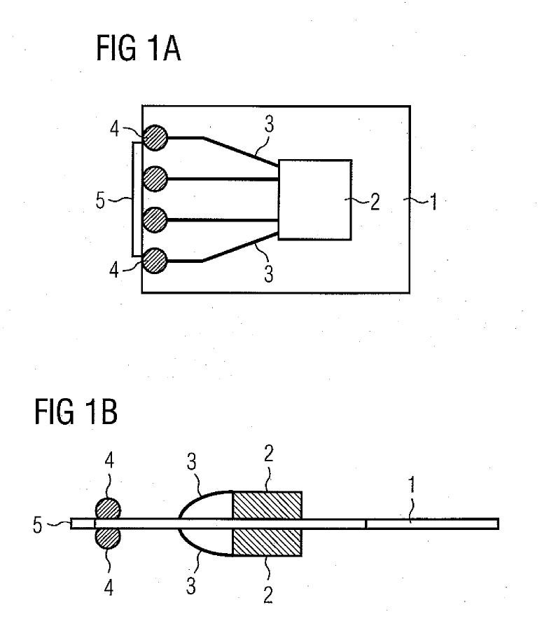

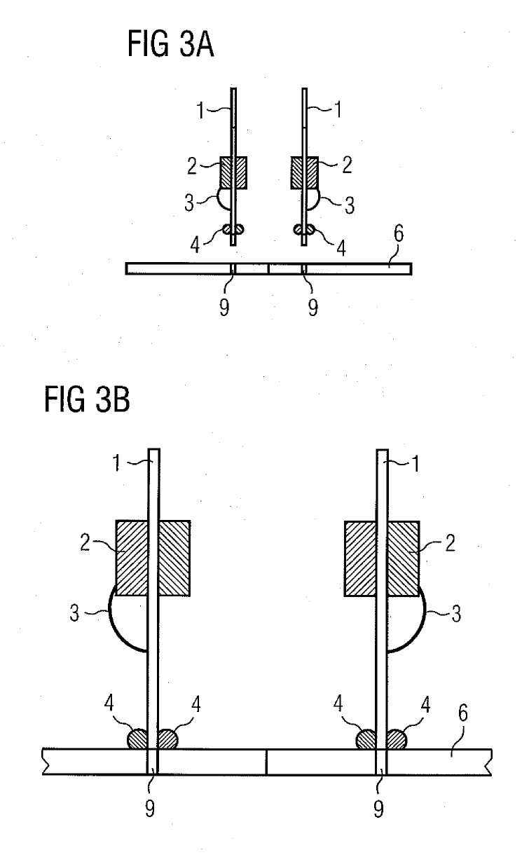

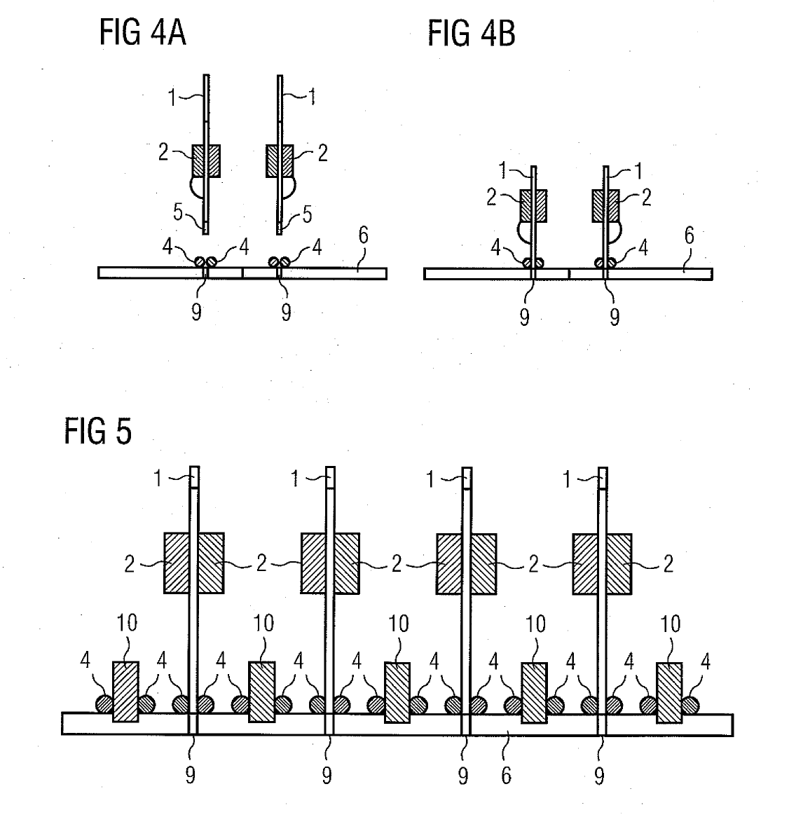

FIG. 1A illustrates a schematic representation of a front view on a substrate 1 for an electronic device in accordance with a first embodiment. The substrate comprises a chip 2 applied on the substrate 1, for instance, by using die bonding, wire bonding, and/or flip chip bonding. At one side of the substrate 1, a projection 5 is formed that projects from the edge of the substrate 1 and extends almost over the entire length of the corresponding side of the substrate 1. The projection 5 serves for the connection with a basis substrate, which will be described below with reference to FIGS. 3 and 4.

The chip 2 is electrically contacted via wire lines 3 that bond the chip 2 to electric contact points of the substrate 1. In the embodiment represented, the contact points of the substrate 1 are formed as solder balls 4. The solder balls 4 may be arranged on the front side or on the rear side of the substrate 1 such that they are positioned in parallel and close to the edge of the substrate 1 at which the projection 5 is formed. This way, the solder balls 4 are arranged on the front and rear sides of the substrate 1 in one plane parallel to the edge of the substrate 1.

FIG. 1B illustrates a schematic representation of a cross-section through the substrate 1 for an electronic device illustrated in FIG. 1A in accordance with a first embodiment. FIG. 1B illustrates that both on the front side and on the rear side of the substrate 1 a chip 2 may be arranged which is bonded via respective wire bondings 3 to the contact points of the substrate 1 which are formed as solder balls 4. The solder balls 4 are also arranged both on the front side and on the rear side of the substrate 1 in a line and are each directly adjacent to the Projection 5 of the substrate 1.

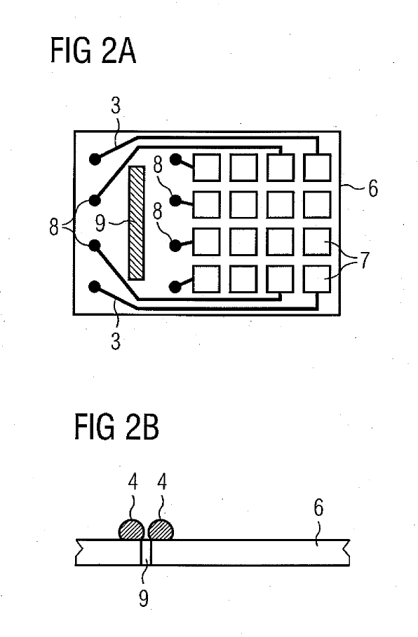

FIG. 2A illustrates a schematic representation of a front view on a basis substrate 6 for an electronic device in accordance with an embodiment. The basis substrate 6 comprises a plurality of chips or other electric devices 7 that were applied on the basis substrate 6. In the main face of the basis substrate 6 there is formed a recess or milled-out portion 9 which, in the illustrated embodiment, extends over the entire thickness of the basis substrate 6 and which extends almost over the entire breadth of the basis substrate 6. The recess or milled-out portion 9 serves for the connection with the substrate 1, which will be described further below with reference to FIGS. 3 and 4.

The chips 7 on the basis substrate 6 are electrically contacted via wire lines 3 that lead to conductive elements 8 of the basis substrate 6. In the illustrated embodiment, the contact points of the substrate 1 are formed as contact faces that are arranged on the front side or on the rear side of the basis substrate 6 such that they are positioned in parallel and close to the edge of the recess 9. This way, the conductive elements of the basis substrate 6 formed as contact faces 8 can correspond with the contact points of the substrate 1 as soon as they are coupled to each other.

FIG. 2B illustrates the schematic representation of a cross-section through a part of the basis substrate for an electronic device illustrated in FIG. 2A in accordance with one embodiment. The conductive elements 8 of the basis substrate may not be formed as contact face, but as solder balls 4. FIG. 2A illustrates that the conductive elements 8 of the basis substrate formed as solder balls 4 are arranged in a line on the main face thereof and are each directly adjacent to the recess 9 of the basis substrate 6.

FIGS. 3A, 3B and 4A, 4B each show the process with which a substrate 1 is coupled with a basis substrate 6, wherein the projection 5 of the substrate 1 is respectively plugged into the recess 9 of the basis substrate 6. FIG. 3A illustrates a schematic representation of the situation prior to the bonding, and FIG. 3B illustrates a schematic representation of the situation after the bonding of the substrate 1 illustrated in FIGS. 1A and 1B and the basis substrate 6 illustrated in FIG. 2A in accordance with one embodiment of the method.

In the state illustrated in FIG. 3A, the substrates 1 are positioned with their projections 5 each directly above the recesses 9 in the basis substrate 6. The first substrates 1 are now introduced vertically into the provided millings or recesses 9 of the second substrate or the basis substrate 6, respectively. It is thus the matter of a vertical nesting of two substrates 1, 6, wherein the plugging via the pivot/groove connection is performed as a mechanical connection between the recess 9 in the basis substrate 6 and the projection 5 of the substrate 1, whereas the electric contact is established via the solder balls 4 and the conductive elements 8 or the contact points, respectively.

The dimensions of the recess 9 in the basis substrate 6 and the dimensions of the projection 5 of the substrate 1 are chosen such that a plug connection with clamping effect results between the recess 9 in the basis substrate 6 and the projection 5 of the substrate 1 in the mounted state. The length of the projection 5 corresponds approximately to the thickness of the basis substrate 6, so that the projection 5 plugged in the recess 9 of the basis substrate 6 reaches exactly to the other side of the basis substrate 6. Additionally, the conductive elements 8 on the basis substrate 6 and the corresponding contact points 4 on the substrates 1 are arranged and dimensioned such that a clamping effect results therebetween in the mounted state.

The distance of the solder ball rows from the edge of the substrate 1, 6 is also chosen such that, with complete plugging of the projection 5 of the first substrate 1 in the recess 9 of the second substrate or the basis substrate 6, respectively, the solder balls 4 of the first substrate come to lie exactly on the contact faces of the corresponding contact points on the surface of the second substrate 6 so as to ensure the electric connection between the substrates 1, 6.

By the nesting of the first substrates 1 with the basis substrate 6, the substrates 1 are in a simple and space-saving manner arranged to stand vertically side by side on the basis substrate 6. After the mechanical and electric coupling, the solder balls 4 and the conductive elements 8 can be soldered in that the solder balls 4 made of solder are heated until the solder of the solder balls 4 produces a solder connection with the corresponding contact faces 8.

In one embodiment of the electronic device, only two-dimensional substrates 1, 6 are required which can each be processed by using standard processes and be provided with chips 2, 7 or other electric components without a complex deforming, bending, or angling of the substrates 1, 6 being necessary (as with MID or with the flex substrate or the rigid-flex-rigid substrate).

FIG. 4A illustrates a schematic representation of the situation prior to the bonding, and FIG. 4B illustrates a schematic representation of the situation after the bonding of a substrate 1 with a basis substrate 6 in accordance with a second embodiment. As already explained above, for bonding the two substrates, the solder balls may either be arranged on the one substrate 1, 6 or on the other substrate 1, 6, and the contact faces may be formed on the respective other substrate 1, 6. In the embodiments illustrated in FIGS. 4A and 4B, the solder balls 4 are arranged on the basis substrate 6 directly adjacent to the recess 9, and corresponding contact faces that are directly adjacent to the projection 5 of the substrate 1 are formed on the substrate 1.

As already explained with respect to FIGS. 3A and 3B, the substrates 1 are plugged with their projections 5 in the recesses 9 in the basis substrate 6, wherein the solder balls 4 on the basis substrate 6 get into contact with the corresponding contact faces on the substrates 1. The electric contacting is thus effected automatically on plugging of the substrates 1 in the basis substrate 6.

Chips or other devices 2 that require a parallel orientation to the circuit board of the basis substrate 6 may be applied by using standard processes (die wire bonding or flip chip bonding) to stand vertically on the substrate 1 that is in turn applied vertically on the basis substrate 6. Thus, the components standing vertically on the substrate 1 are conveyed to a parallel position with respect to the circuit board of the basis substrate 6.

FIG. 5 illustrates a schematic representation of an electronic device in accordance with a third embodiment. Instead of vertically standing substrates 1, chips 10 may also be inserted directly to stand vertically in the basis substrate 6. FIG. 5 illustrates how, in addition to the substrates 1, chips 10 are also plugged into recess 9 to stand vertically in the basis substrate 6. In so doing, the chips 10 are contacted in the same above-described manner via the bonding of solder balls 4 and corresponding contact faces. To this end, either the chips 10 are provided with solder balls 4 and the basis substrate with the corresponding contact faces, or vice versa.

One advantage of this embodiment consists in that the substrate costs can be reduced vis-à-vis the providing with substrates 1. Furthermore, complex special processes become superfluous, and thus the manufacturing costs are reduced vis-à-vis the previous solutions for the providing of substrates 6 with chips 10. For the manufacturing of a SiP (“System in Package”), the chips 10 may be arranged to stand vertically by using the vertical wiring possibility. A plurality of vertically arranged substrates enable a space-saving lining-up and contacting of chips and SMDs (“surface mount device”) in contrast to previous constructions in which the chips are each arranged in parallel to the basis substrate (“stacking”).

The individual substrates can be tested after mounting and wiring, e.g., by die wire flip chip bonding. Chips and SMDs (“surface mount device”) may be accommodated both on the vertical and on the horizontal substrate. The chip mounting may be decoupled from the SMD mounting since chips and SMDs can be applied on different substrates.

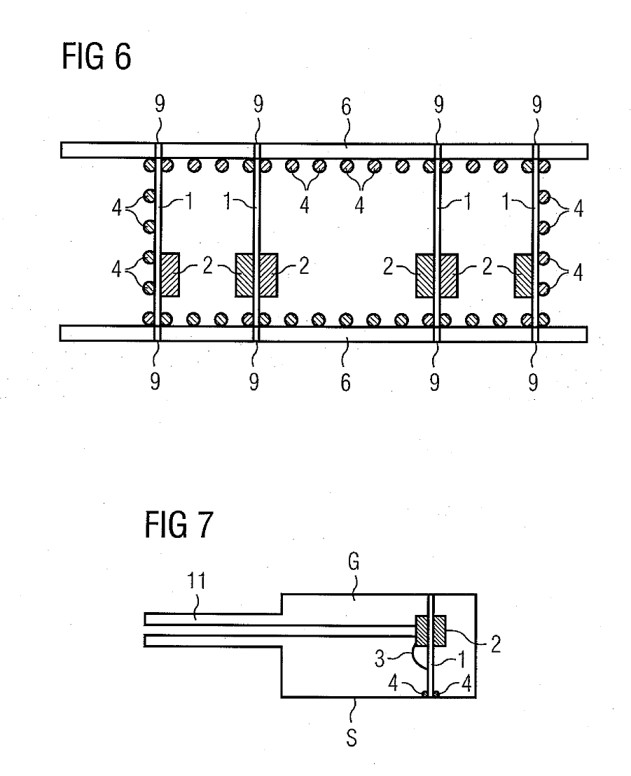

FIG. 6 illustrates a schematic representation of a cross-section of an electronic device in accordance with a fourth embodiment. In the embodiment illustrated in FIG. 6, the substrates 1 that are standing vertical with respect to the basis substrate 6 are not just arranged side by side, but also at angles to each other. The solder balls 4 are accordingly not just arranged in a row, but circumferentially, so that cover and side substrates can also be placed and electrically contacted.

With this embodiment already by the angled arrangement of the substrates 1 with cover and side substrates, an electronic device with stacked construction results, the inner volume of which is better protected from external electromagnetic scattered radiation by the surrounding substrates 1. This effect of shielding may be increased in that at least the outer substrates 1, cover and/or bottom substrates or the basis substrate, respectively, comprise shield layers. Thus, the inner sides of the shield faces may simultaneously serve as carriers for chips and SMDs (“surface mount device”).

FIG. 7 illustrates a schematic representation of a cross-section through an electronic device in accordance with a fifth embodiment. The embodiment illustrated in FIG. 7 was provided with a package G by using molding which surrounds the components of the electronic device at least partially.

Instead of applying chips and/or SMD components (“surface mount device”) prior to molding, the electronic device may also be molded such that the vertically standing substrate 1 is left completely or partially open on one side in that a separately mounted substrate, a submount 11, is glued or soldered to the substrate 1. In the case of an optical device, for instance, an opening may take care that light may get from or to the optical chip on the submount 11. This mounting of a submount 11 has the advantage that during its gluing or soldering the optical axis can be adjusted independently of die bond and coating process tolerances.

In the embodiment illustrated in FIG. 6, the solder balls 4 are applied on both sides of the substrate 1 in a line at the outer end of the substrate 1. After the molding or casting of the entire device bar (not illustrated), the devices are individualized such that half a solder ball 4 each remains in the package G and the exposed circle face can be used as a solderable connection. To this end, the cutting area S is placed such during the sawing of the device bar that it extends directly through the largest diameter of the solder balls 4. This way, cutting areas of the solder balls 4 are generated which constitute a part of the outer face of the package G and are thus easy to contact from outside.

The package G that has been provided this way is adapted to be provided vertically with the connection faces of the solder balls 4 downward and thus has, for instance, a connection to an optical fiber or a pressure tube. The vertical wiring consequently results from the sawing of three-dimensional contacting structures, preferably solder balls, which are applied on a substrate that carries the chips or other electronic devices, wherein the saw face is positioned vertically to the face of the substrate 1.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An electronic device comprising:
a basis substrate and a number of further substrates that are bonded to the basis substrate via a three-dimensional wiring structure; and
the number of substrates are each provided with at least one projection that extends from the substrate while the basis substrate comprises a number of recesses that are designed such that they are each adapted to accommodate the projection of the substrate, wherein the basis substrate comprises electroconductive elements that are configured in the edge region of a recess so as to cooperate with the electric contact points of the substrates.

2. The electronic device of claim 1, comprising:
where the substrates, in the mounted state, are each mechanically coupled via the projection accommodated in the recesses.

3. The electronic device of claim 2, comprising:
the number of substrates each comprise one or a plurality of integrated circuits and/or electronic devices as well as electric contact points for the electric contacting of the integrated circuits and/or electronic devices.

4. The electronic device of claim 3, comprising:
the integrated circuits and/or the electronic devices of the substrates are electrically connected with the conductive elements of the basis substrate.

5. The electronic device of claim 1, comprising wherein the number of substrates in the mounted state are each oriented substantially vertically with respect to the basis substrate.

6. The electronic device of claim 1, comprising wherein at least one conductive element on the basis substrate is formed as a solder ball.

7. The electronic device of claim 6, comprising wherein the solder balls on the basis substrate are directly adjacent to the edge of the recess.

8. The electronic device of claim 1, wherein the solder balls on the basis substrate comprise a cutting area.

9. The electronic device of claim 8, comprising wherein the cutting area of the solder balls on the basis substrate extend in the region of the maximum diameter of the solder ball.

10. The electronic device of claim 1, comprising wherein the cutting areas of the cut solder balls on the basis substrate are directly adjacent to the edge of the recess.

11. The electronic device of claim 1, comprising wherein the cutting areas of the cut solder balls on the basis substrate are each aligned with the edge of the recess.

12. The electronic device of claim 1, wherein the cutting areas of the cut solder balls on the basis substrate comprise at least partially an inclined orientation deviating from the alignment of the recess.

13. An electronic device comprising:
a basis substrate and a number of further substrates that are bonded to the basis substrate via a three-dimensional wiring structure;
wherein the number of substrates each comprise one or a plurality of integrated circuits and/or electronic devices as well as electric contact points for the electric contacting of the integrated circuits and/or electronic devices, and wherein the number of substrates are each provided with at least one projection that extends from the substrate while the basis substrate comprises a number of recesses that are designed such that they are each adapted to accommodate the projection of the substrate; and
wherein the basis substrate comprises electroconductive elements that are arranged in the edge region of a recess so as to cooperate with the electric contact points of the substrates, so that the substrates, in the mounted state, are each mechanically coupled via the projection accommodated in the recesses, and the integrated circuits and/or the electronic devices of the substrates are electrically connected with the conductive elements of the basis substrate.

14. The electronic device of claim 13, comprising wherein at least one contact point for the electric contacting of the integrated circuits and/or electronic devices on the substrate is formed as a solder ball.

15. The electronic device of claim 13, comprising wherein the solder balls on the substrate are directly adjacent to the projection of the substrate.

16. The electronic device of claim 13, comprising wherein the solder balls on the substrate comprise a cutting area.

17. The electronic device of claim 16, comprising wherein the cutting area of the solder balls on the substrate extends in the region of the maximum diameter of the solder ball.

18. The electronic device of claim 13, comprising wherein the cutting area of the cut solder balls on the substrate is oriented substantially vertically to the orientation of the projection of the substrate.

19. The electronic device of claim 13, comprising wherein the conductive elements on the basis substrate are arranged such that they correspond with the electric contact points on the substrates in the mounted state so as to establish an electric contact.

20. The electronic device of claim 19, comprising wherein the conductive elements on the basis substrate and the corresponding electric contact points on the substrates are arranged such that a clamping effect results therebetween in the mounted state.

21. The electronic device of claim 13, comprising wherein at least one conductive element on the basis substrate is formed as a contact face.

22. The electronic device of claim 13, comprising wherein at least one contact point for the electric contacting of the integrated circuits and/or electronic devices on the substrates is formed as a contact face.

23. The electronic device of claim 13, comprising wherein the projection extends from the edge at one side of the substrate.

24. The electronic device of claim 13, comprising wherein a plurality of projections are provided at one side of the substrate.

25. The electronic device of claim 13, comprising wherein at least one projection each is provided at several sides of the substrate.

26. The electronic device of claim 13, comprising wherein the dimensions of the recess in the basis substrate correspond substantially to the dimensions of the projection of a substrate, so that a plug connection of the principle of a pivot/groove connection results between the recess in the basis substrate and the projection of a substrate in the mounted state.

27. The electronic device of claim 13, comprising wherein the length by which the projection extends from the substrate corresponds substantially to the thickness of the basis substrate.

28. The electronic device of claim 13, comprising wherein the recess in the basis substrate and the projection of a substrate are designed such that a clamping effect results between the recess in the basis substrate and the projection of a substrate in the mounted state.

29. The electronic device of claim 13, wherein the number of substrates comprise at least one chip with one or a plurality of integrated circuits and/or electronic devices which is introduced into the recess of the basis substrate.

30. The electronic device of claim 13, comprising wherein the integrated circuits and/or electronic devices on the substrate are electrically contacted via the electric contacts of the substrate and the conductive elements on the basis substrate.

31. The electronic device of claim 13, wherein the electronic device comprising the basis substrate and the substrates arranged thereon are at least partially surrounded by a package, wherein at least some of the conductive elements of the basis substrate and/or the contact points of the substrates are contactable from outside the package.

32. The electronic device of claim 31, comprising wherein at least some of the conductive elements of the basis substrate and/or the contact points of the substrates constitute a part of the outer face of the package.

33. The electronic device of claim 13, wherein at least the outer substrates and/or the basis substrate comprise shield layers.

34. A method for manufacturing an electronic semiconductor device with a basis substrate and a number of further substrates that are bonded to the basis substrate via a three-dimensional wiring structure, the method comprising:
providing at least one substrate comprising electric contact points and at least one projection that extends from the substrate;
providing a basis substrate comprising at least one recess that is designed such that it is adapted to accommodate the projection of a substrate, and conductive elements that are arranged in the edge region of the recess;
mounting the substrate on the basis substrate by introducing the at least one projection of the substrate in a recess in the basis substrate; and
contacting the contact points on the substrate via the conductive elements on the basis substrate.

35. The method of claim 34, further comprising the electric contacting of the integrated circuits and/or electronic devices on the substrate via the electric contacts of the substrate and the conductive elements on the basis substrate.

36. The method of claim 34, further comprising fusing the contact points of the substrates with the corresponding conductive elements on the basis substrate by heating.

37. The method of claim 34, further comprising at least partially enclosing of the electronic device comprising the basis substrate and the substrates arranged thereon in a package, wherein the conductive elements of the basis substrate and/or the contact points of the substrates remain contactable at least partially from outside the package.

38. The method of claim 37, comprising producing a cutting area at the package such that a respective part of the conductive elements of the basis substrate formed as solder balls and/or of the contact points of the substrates formed as solder balls remains in the package, and the cutting area of the solder balls constitutes a part of the outer face of the package and can be used as exposed, solderable connection.

39. The method of claim 38, comprising generating the cutting area at the package such that the cutting area of the solder balls is oriented vertically to the face of the substrate.
